(19) United States
(12) Patent Application Publication
(10) Pub. No.: US 2024/0110081 A1
(43) Pub. Date: Apr. 4, 2024

(54) TEMPORARY SUBSTRATE ADHESIVE AND SUBSTRATE PROCESSING METHOD

(71) Applicant: KABUSHIKI KAISHA TOSHIBA, Tokyo (JP)

(72) Inventors: Masaaki HIRAKAWA, Yokohama (JP); Kazushi TATEYAMA, Yokohama (JP)

(73) Assignee: KABUSHIKI KAISHA TOSHIBA, Tokyo (JP)

(21) Appl. No.: 18/522,376

(22) Filed: Nov. 29, 2023

Related U.S. Application Data
(62) Division of application No. 17/694,050, filed on Mar. 14, 2022.

(30) Foreign Application Priority Data
Sep. 22, 2021 (JP) 2021-153826

(51) Int. Cl. C09J 4/00; B29C 65/02; B29C 65/48

(52) U.S. Cl. CPC C09J 4/00; B29C 65/02; B29C 65/4825; B29L 2031/3425

(57) ABSTRACT

A temporary substrate adhesive according to an embodiment includes a silane coupling agent and a photobase generator, but does not include a resin.

### CROSS-REFERENCE TO RELATED APPLICATIONS

This application is a divisional of and claims benefit under 35 U.S.C. § 120 to U.S. application Ser. No. 17/694,050 filed Mar. 14, 2022, and claims the benefit of priority under 35 U.S.C. § 119 from Japanese Patent Application No. 2021-153826, filed Sep. 22, 2021, the entire contents of each of which are incorporated herein by reference.

### FIELD

Embodiments described herein relate generally to a temporary substrate adhesive and a substrate processing method.

### BACKGROUND

There is a processing method of a substrate in which a processing substrate and a support substrate are bonded using a temporary substrate adhesive, and the processing substrate and the support substrate are detached after processing the processing substrate. It is desirable for the temporary substrate adhesive used in such a processing method to have excellent heat resistance after bonding, and it is desirable to suppress residue of the adhesive after detaching.

### BRIEF DESCRIPTION OF THE DRAWINGS

FIGS. 1A to 1F are explanatory drawings showing the substrate processing method according to the embodiment; and

FIGS. 2A and 2B are explanatory drawings of the experimental example.

### DETAILED DESCRIPTION

A temporary substrate adhesive according to an embodiment includes a silane coupling agent and a photobase generator, but does not include a resin.

Exemplary embodiments will now be described with reference to the drawings.

The drawings are schematic or conceptual; and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions.

In the specification of the application and the drawings, components similar to those described in regard to a drawing thereinabove are marked with like reference numerals; and a detailed description is omitted as appropriate.

### Temporary Substrate Adhesive

A temporary substrate adhesive according to an embodiment includes a silane coupling agent and a photobase generator. The temporary substrate adhesive according to the embodiment does not include a resin.

The silane coupling agent includes, for example, a silanol group. The silane coupling agent includes, for example, at least one selected from the group consisting of an amino group, an epoxy group, an azido group, and an isocyanate group. By including such functional groups, the silane coupling agent can bind with a hydroxide group of the front surface of the processing substrate and/or an amino group or carboxyl group formed of a partially-cleaved imide bond of a polyimide film formed at the front surface of the processing substrate. The silane coupling agent may include other functional groups that can bind with the hydroxide group of the front surface of the processing substrate and/or the amino group or carboxyl group formed of the partially-cleaved imide bond of the polyimide film. For example, these functional groups bind to silicon atoms included in siloxane bonds.

By including a silanol group, the silane coupling agent can easily bind with a hydroxide group of the front surface of the support substrate. The silane coupling agent may include other functional groups that can bind with the hydroxide group of the front surface of the support substrate.

For example, the silane coupling agent has a structure represented by the following Formula (1) or Formula (2). Formula (2) shows a hydrolysis reaction of a silane coupling agent having a fundamental chemical structure.

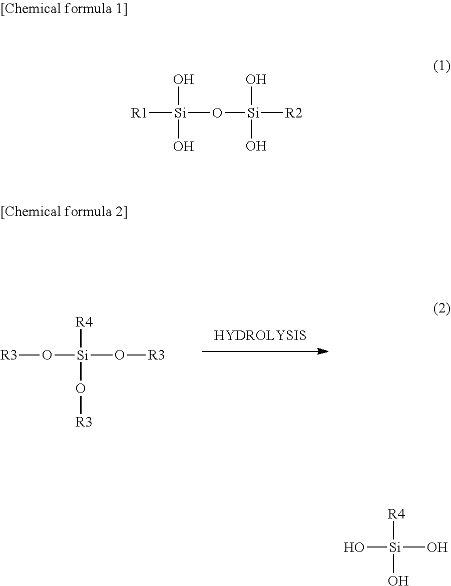

(In the formulas, R1, R2, and R4 are respectively an amino group, an epoxy group, and an azido group or isocyanate group. R3 is a methyl group or ethyl group).

The blending amount of the silane coupling agent is, for example, not less than 0.1 mass % and not more than 1 mass % of the temporary substrate adhesive.

For example, the photobase generator generates a base by absorbing ultraviolet light having a wavelength that is not more than 400 nm. For example, the photobase generator generates a base by absorbing ultraviolet light having a wavelength that is not more than 254 nm.

For example, the photobase generator has a structure illustrated by the following Formula (3), Formula (4), or Formula (5).

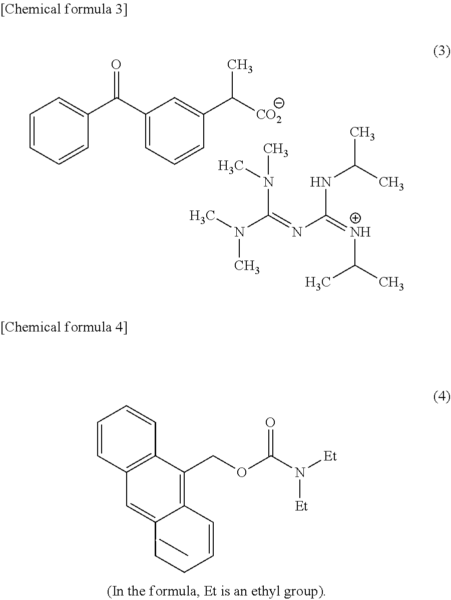

(In the formula, Et is an ethyl group).

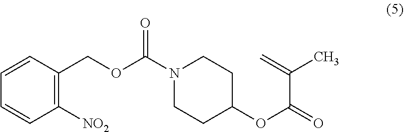 [SMILES: C=C(C)C(=O)OC1CCN(C(=O)OCc2ccccc2[N+](=O)[O-])CC1]

The blending amount of the photobase generator is, for example, not less than 0.01 mass % and not more than 0.1 mass % of the temporary substrate adhesive.

The temporary substrate adhesive according to the embodiment may include, for example, a solvent. For example, methanol, ethanol, isopropyl alcohol, etc., are examples of the solvent.

### Substrate Processing Method

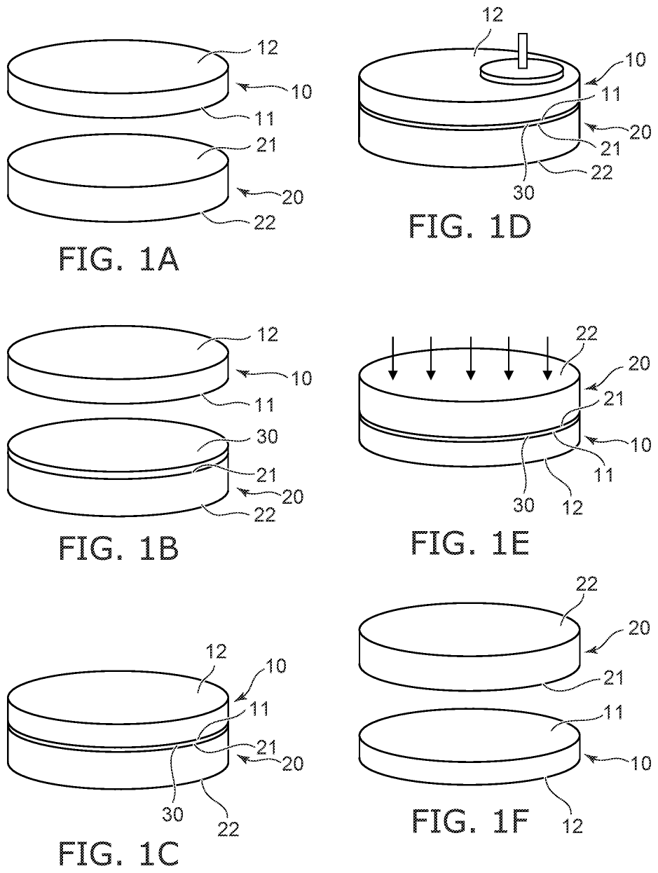

FIGS. 1A to 1F are explanatory drawings showing the substrate processing method according to the embodiment.

As illustrated in FIGS. 1A to 1F, the substrate processing method according to the embodiment processes one surface (a second surface 12 described below) of a processing substrate 10. The substrate processing method according to the embodiment includes a bonding process, a processing process, and a detaching process. The substrate processing method according to the embodiment will now be described in more detail.

In the substrate processing method according to the embodiment, first, the processing substrate 10 and a support substrate 20 are prepared as illustrated in FIG. 1A.

The processing substrate 10 is, for example, a wafer. For example, the processing substrate 10 has a device structure. The processing substrate 10 includes, for example, a semiconductor.

The processing substrate 10 includes a first surface 11 and the second surface 12. The first surface 11 is a bonding surface that is bonded with the support substrate 20. The second surface 12 faces away from the first surface 11. The second surface 12 is the back surface when the first surface 11 is taken as the front surface. The second surface 12 is the processing surface that is processed in the processing process. For example, a circuit is pre-formed in the first surface 11. The first surface 11 is, for example, a circuit formation surface. For example, a circuit is not pre-formed in the second surface 12. The second surface 12 is, for example, a non-circuit-formation surface. A film that includes polyimide may be formed at the first surface 11.

The support substrate 20 is transmissive to ultraviolet light. For example, the support substrate 20 is transmissive to ultraviolet light having a wavelength that is not more than 300 nm. For example, the support substrate 20 is transmissive to ultraviolet light having a wavelength that is not more than 254 nm. The support substrate 20 is, for example, transparent. The light transmittance of the support substrate 20 is, for example, greater than the light transmittance of the processing substrate 10. The support substrate 20 includes, for example, synthetic quartz.

The support substrate 20 includes a third surface 21 and a fourth surface 22. The third surface 21 is a bonding surface that is bonded with the processing substrate 10. The fourth surface 22 faces away from the third surface 21. The fourth surface 22 is the back surface when the third surface 21 is taken as the front surface.

Then, in the substrate processing method according to the embodiment as illustrated in FIG. 1B, a temporary substrate adhesive 30 is coated between the processing substrate 10 and the support substrate 20. The temporary substrate adhesive 30 is the temporary substrate adhesive according to the embodiment described above. In other words, the temporary substrate adhesive 30 includes a silane coupling agent and a photobase generator but does not include a resin. For example, the temporary substrate adhesive 30 is coated by spin coating.

The temporary substrate adhesive 30 is coated onto at least one of the first surface 11 of the processing substrate 10 or the third surface 21 of the support substrate 20. In the example, the temporary substrate adhesive 30 is coated onto the third surface 21 of the support substrate 20. The temporary substrate adhesive 30 may be coated onto the first surface 11 of the processing substrate 10, or may be coated onto both the first surface 11 of the processing substrate 10 and the third surface 21 of the support substrate 20.

Then, in the substrate processing method according to the embodiment as illustrated in FIG. 1C, the processing substrate 10 and the support substrate 20 are bonded by thermal compression bonding. The thermal compression bonding chemically bonds the first surface 11 of the processing substrate 10 and the third surface 21 of the support substrate 20 via the temporary substrate adhesive 30 (the silane coupling agent). When a film that includes polyimide is formed at the first surface 11, the film that includes polyimide and the third surface 21 of the support substrate 20 are chemically bonded via the temporary substrate adhesive 30 (the silane coupling agent). For example, the thermal compression bonding is performed using conditions of not less than 100° C. and not more than 160° C., not less than 1.25 MPa and not more than 5 MPa, and not less than 15 minutes and not more than 30 minutes.

The coating of the temporary substrate adhesive 30 Illustrated in FIG. 1B and the thermal compression bonding illustrated in FIG. 1C correspond to the bonding process.

Then, in the substrate processing method according to the embodiment as illustrated in FIG. 1D, the second surface 12 of the processing substrate 10 is processed (the processing process). The processing process includes, for example, at least one of grinding the second surface 12, polishing the second surface 12, film formation on the second surface 12, or heating the second surface 12. The processing process is performed after the bonding process.

Continuing, in the substrate processing method according to the embodiment as illustrated in FIGS. 1E and 1F, the processing substrate 10 and the support substrate 20 are detached by irradiating ultraviolet light from the fourth surface 22 side of the support substrate 20. More specifically, the first surface 11 of the processing substrate 10 and the third surface 21 of the support substrate 20 are detached. When a film that includes polyimide is formed at the first surface 11, the film that includes polyimide and the third surface 21 of the support substrate 20 are detached. The detaching process is performed after the processing process.

For example, the ultraviolet light that is irradiated has a wavelength that is not more than 400 nm. For example, the ultraviolet light that is irradiated has a wavelength of 200 to 280 nm. The light irradiation amount of the ultraviolet light is, for example, not less than 190 J/cm² and not more than 300 J/cm². The detachment may be performed after leaving idle for a prescribed period of time (e.g., about 15 minutes) after irradiating of the ultraviolet light.

When the ultraviolet light is irradiated, the photobase generator that is included in the temporary substrate adhesive absorbs the ultraviolet light and generates a base. For example, the bonds between the silane coupling agent and the first surface 11 of the processing substrate 10 are broken by the generated base. When a film that includes polyimide is formed at the first surface 11, for example, the bonds between the silane coupling agent and the film that includes polyimide are broken by the generated base. For example, the bonds between the silane coupling agent and the third surface 21 of the support substrate 20 are broken by the generated base. The processing substrate 10 and the support substrate 20 can be detached thereby.

For example, the detached support substrate 20 can be re-utilized as the support substrate 20 in the next processing.

Effects of the temporary substrate adhesive and the substrate processing method according to the embodiment will now be described.

Temporary substrate adhesives that include a thermosetting resin or a photocurable resin (e.g., an acrylic resin, a silicone resin, etc.) have conventionally been used. However, when using such a temporary substrate adhesive that includes a resin to bond a processing substrate and a support substrate, the tolerable temperature of the bonding portion is dependent on the tolerable temperature of the resin and is not more than about 200° C. Therefore, for example, when the temperature of the processing substrate reaches or exceeds 200° C. when processing after bonding, the processing substrate undesirably detaches unexpectedly from the support substrate.

Also, when using such a temporary substrate adhesive that includes a resin to bond the processing substrate and the support substrate, there are cases where “adhesive residue” occurs in which a portion of the temporary substrate adhesive remains on the processing substrate and/or the support substrate after the processing substrate and the support substrate are detached. When adhesive residue occurs, a process of cleaning the processing substrate and/or the support substrate with an organic solvent, etc., after detaching becomes necessary and may reduce the yield of the substrate processing. It is therefore desirable for the temporary substrate adhesive used in such a substrate processing method to have excellent heat resistance after bonding, and for the adhesive residue after detaching to be suppressed.

Conversely, according to the temporary substrate adhesive according to the embodiment, the silane coupling agent includes a photobase generator but does not include a resin; therefore, the processing substrate and the support substrate can be reliably bonded, the heat resistance after bonding is excellent, and the adhesive residue after detaching can be suppressed.

Also, by using such a temporary substrate adhesive according to the embodiment in the substrate processing method according to the embodiment, the heat resistance after bonding can be excellent, and the adhesive residue after detaching can be suppressed. Accordingly, the degree of freedom of the processing in the processing process can be increased, the cleaning process after detaching can be omitted, and the yield can be increased.

For example, the temporary substrate adhesive and the substrate processing method according to the embodiment are used to manufacture power devices and LED devices.

### Experimental Example

An experimental example will now be described.

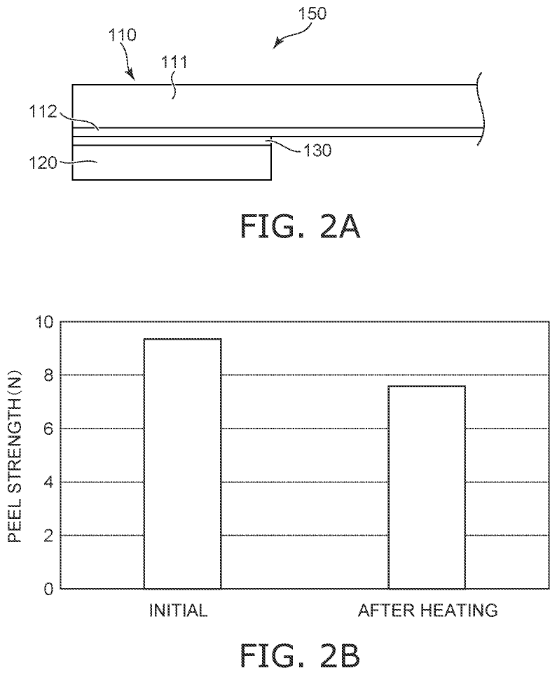

FIGS. 2A and 2B are explanatory drawings of the experimental example.

In the experimental example, first, as illustrated in FIG. 2A, a test piece 110 in which a film 112 made of polyimide was formed on the front surface of a metal plate 111 was prepared; and a support substrate 120 made of synthetic quartz having a thickness of 1.0 mm was prepared. Then, bonding samples 150 were made by using temporary substrate adhesives 130 to bond the test piece 110 and the support substrate 120 by using thermal compression bonding. The temporary substrate adhesives 130 were made by using the silane coupling agent represented by Formula (1) recited above in which R1 and R2 are ethylenediamine groups, and by using the photobase generator represented by Formula (2) recited above.

The peel strength (the initial peel strength) when detaching the support substrate 120 from the test piece 110 was measured for the bonding samples 150 thus made. Similarly, the peel strength (the peel strength after heating) when detaching the support substrate 120 from the test piece 110 was measured for the bonding samples 150 thus made after heating in a nitrogen atmosphere at 400° C. for 120 minutes. The results are illustrated in FIG. 23.

As illustrated in FIG. 2B, when heating is performed and when heating is not performed, a peel strength that was not less than 7 N was obtained, and the bonding was strong enough that the film 112 was torn by the detachment. This suggests that a large reduction of the peel strength after the heating can be suppressed by using the temporary substrate adhesive 130 to bond the test piece 110 and the support substrate 120. In other words, this suggests that the heat resistance after bonding is excellent.

Then, the bonding samples 150 were made similarly to those described above and subjected to heating in a nitrogen atmosphere at 400° C. for 120 minutes; 287 J/cm² of ultraviolet light having the wavelength of 200 to 280 nm was irradiated; and the test piece 110 and the support substrate 120 were detached after leaving idle for 15 minutes. As a result, the test piece 110 and the support substrate 120 could be easily detached without adhesive residue at the bonding surface after detaching. Therefore, this suggests that by using the temporary substrate adhesive 130 to bond the test piece 110 and the support substrate 120, even after heating is performed, the detachment can be performed more easily by irradiating ultraviolet light and without causing adhesive residue after detaching. In other words, this suggests that the adhesive residue after detaching can be suppressed.

According to embodiments as described above, a temporary substrate adhesive and a substrate processing method are provided in which the heat resistance after bonding is excellent and the adhesive residue after detaching can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions. Embodiments described above can be implemented in combination with each other.

What is claimed is:

1. A temporary substrate adhesive including a s lane coupling agent and a photobase generator but not including a resin.

2. The temporary substrate adhesive according to claim 1, wherein
the silane coupling agent includes at least one selected from the group consisting of an amino group, an epoxy group, an azido group, and an isocyanate group.
